(19) United States
(12) Patent Application Publication
(10) Pub. No.: US 2026/0351307 A1
(43) Pub. Date: Nov. 5, 2026

(54) CLOCK SKEW ADAPTIVE SELF-TIME PATH IN DUAL PORT MEMORIES

(71) Applicant: STMicroelectronics International N.V., Geneva (CH)

(72) Inventors: Sant Swaroop SHRIVASTAVA, Agra (IN); Hitesh CHAWLA, Noida (IN); Jagjeet SINGH, Delhi (IN)

(73) Assignee: STMicroelectronics International N.V., Geneva (CH)

(21) Appl. No.: 19/195,927

(22) Filed: May 1, 2025

(51) Int. Cl. G11C 11/419; G11C 5/06; G11C 11/418

(52) U.S. Cl. CPC G11C 11/419; G11C 5/063; G11C 11/418

(57) ABSTRACT

Disclosed herein is a self-timed dual-port static random access memory (SRAM) device with improved timing accuracy for read operations. The device includes an SRAM bank with multiple SRAM cells arranged in rows and columns, and a dummy circuit that includes comprises a dummy read wordline and a complementary dummy read wordline extending through dummy read rows and columns. These dummy wordlines are physically arranged with a proximity relationship that mimics the physical proximity between actual read and write wordlines in the SRAM bank. A dummy read decoder selectively activates the complementary dummy read wordline when a read operation is expected to cause coupling effects between wordlines, creating corresponding coupling effects in the dummy circuit. Control circuitry activates sense amplifiers based on state changes in the dummy read bitline.

### TECHNICAL FIELD

The disclosure relates to a self-timed Static Random Access Memory (SRAM) system employing complementary dummy wordlines to compensate for coupling effects between read and write wordlines.

### BACKGROUND

Now described with reference to FIG. 1 is a self-timed Static Random Access Memory (SRAM) system 10. The SRAM system 10 includes a SRAM array 11, dummy row 12, dummy column 13, row decoder 14, dummy row decoder (DRD) 15, self-timed control logic (LOG) 18, read/write circuitry 19, and input/output (IO) circuitry 20.

The SRAM array 11 is comprised of a grid of multiple rows and columns of eight-transistor (8T) SRAM cells, each capable of storing a single bit of data. In a dual-port SRAM as shown in FIG. 1, each row has separate read wordlines (WLR1, WLR2, . . . , WLRn) and write wordlines (WLW1, WLW2, . . . , WLWn) to facilitate simultaneous read and write operations. The intersections of these wordlines and bitlines (BLT1/BLF1/BLR1, . . . , BLTm/BLFm/BLRm) form individual cells of SRAM array 11 where the bits of data are read from or written to.

For read operations, the read clock (RCK) signal initiates the process by triggering the row decoder 14, which decodes the input address (ADDR) to assert the appropriate read wordline (WLR). The timing of the read wordline activation is controlled by RCK, which ensures proper synchronization of the read operation. When the read wordline is activated, the cells of the selected row in the SRAM array 11 change the states of their corresponding read bitlines (BLR) dependent upon the data stored in those cells. These changes are detected by sense amplifiers within the read/write circuitry 19, which are activated in response to an indication from the self-timed control logic 18 that a dummy read is complete.

For write operations, the write clock (WCK) signal initiates the process by triggering the row decoder 14, which decodes the input address to assert the appropriate write wordline (WLW). The timing of the write wordline activation is controlled by WCK, which ensures proper synchronization of the write operation. Concurrently, the desired data to be written is provided to the bitlines (BLT/BLF) via the input/output circuitry 20. Once the write wordline is activated, the SRAM cell connected to it stores the new data by transitioning to a stable state corresponding to the provided bit value. The self-timed control logic 18 terminates the write operation when the write is complete.

Data input/output (I/O) circuitry 20 interfaces SRAM array 11 with the rest of the system. It delivers the data to be written to the SRAM array 11 and routes the read data to the appropriate system output.

The self-timed control logic 18 controls the read/write circuitry 19 in response to delay tracking effectively performed by the dummy row 12 and dummy column 13. The self-timed control logic 18 receives both the read clock (RCK) and write clock (WCK) signals to coordinate the timing of read and write operations.

For read operations, the dummy row 12 is designed and positioned to track (e.g., emulate) the worst-case delay for each SRAM cell in the selected row to reflect its state change onto its corresponding bit lines during a read operation. The RCK signal triggers this dummy read operation. In addition, the dummy column 13 is designed and positioned to track (e.g., emulate) the worst-case bit line delay during a read operation. The dummy read operation begins with the dummy decoder 15 performing a dummy decode and selection of the dummy word line DWL, resulting in state change of the dummy bit lines. When the dummy row 12 and dummy column 13 complete dummy operations (e.g., the voltage level on the dummy bit line has fallen to a level where it can be assumed that a sense amplifier, when activated, would sense, read, and output the correct data value stored in the dummy cell), it can be inferred that the sense amplifiers within the read/write circuitry can be turned on to read the selected row in the SRAM array 11, as the dummy row 12 accounts for the worst-case delay of the cells to impose the proper state changes on their bit lines.

For write operations, the dummy row 12 is designed and positioned to track (e.g., emulate) the worst-case delay for each SRAM cell in the selected row to accept a new data value during a write operation. The WCK signal triggers this dummy write operation. This accounts for the time it takes for the SRAM cell to store the incoming value. The dummy column 13, during write operations, tracks the worst-case delay associated with establishing the correct data value onto the bit lines, ensuring that the targeted SRAM cell receives the proper data value. The dummy write operation begins with the dummy decoder 15 performing a dummy decode and selection of the dummy word line DWL, and then a write being performed to the dummy cells. When the dummy row 12 and dummy column 13 complete a write operation, it can be assumed that the selected row in the SRAM array 11 has completed its write operation and that the writer drivers within the read/write circuitry 19 can be turned off.

However, in SRAM dual-port architectures where simultaneous read and write operations occur, significant challenges arise due to coupling effects between wordlines. FIG. 2 illustrates the detailed circuit implementation of a dual-port SRAM cell along with its position in the array structure. The left side shows the transistor-level circuitry of an individual SRAM cell with its write wordline (WLW) connected to pass gates PG1 and PG2, and read wordline (WLR) connected to read transistors MN3 and MN4.

The SRAM cell contains complementary storage nodes formed by the cross-coupled inverters INV1 and INV2. These inverters create a bistable circuit that stores a single bit of data. The internal storage nodes connect to the bitlines through several connections: BLT (Bitline True), which carries the true (non-inverted) data value during read/write operations; BLF (Bitline False), which carries the inverted data value, complementary to BLT; BLTI (Bitline True Internal), which is the internal node connecting the true data storage point to the bitline through pass gate PG2; BLFI (Bitline False Internal), which is the internal node connecting the inverted data storage point to the bitline through pass gate PG1; and BLR (Bitline Read), a dedicated bitline specifically for read operations in this dual-port configuration.

The right side of FIG. 2 shows how these cells are arranged in the SRAM array with multiple rows and columns.

In these simultaneous read and write operations, three primary types of coupling can occur: WLW coupling on WLR, which is especially prominent because both wordlines reside in the same metal layer; WLW coupling on BLTI, where the write wordline affects the internal bitline true node within the cell; and BLT/BLF coupling on WLR, where the bitlines (true and false) interfere with the read wordline. Among these, the WLW coupling on WLR represents the most significant concern due to the physical proximity of these lines in the metal layer, as seen in FIG. 2. The result of this coupling is degradation of the slope of the signal on the effected line (e.g., degradation of the slope of the signal on WLR when WLR is asserted).

The effect of this coupling is particularly severe when the slope is heavily degraded. As illustrated in the discharging case trend graph in FIG. 3, the read self-time margin exhibits significant degradation when there is timing offset between WCK and RCK. This timing offset, referred to as “clock skew,” represents the difference in arrival time between the two clock signals, and results in the degradation of the slope of the signal on the effected line. The x-axis of the graph in FIG. 3 shows this clock skew, where negative values indicate that WCK arrives before RCK, and positive values indicate that RCK arrives before WCK. The y-axis shows the normalized read self-time margin. The graph clearly demonstrates that certain skew values between the clocks can cause a dramatic degradation in timing margins.

FIG. 4 provides a clear illustration of the clock skew and its effect on coupling at the signal level. As shown in the waveform diagram, when WLW transitions, it induces a coupling effect on WLR. The dotted circle highlights the critical area where this coupling manifests as a distortion in the WLR waveform during its rising edge. This distortion directly reduces the discharge current available during the read operation, as indicated by the annotation. The reduced discharge current slows down the bitline development time, which in turn degrades the self-timing margins of the SRAM. This specific mechanism explains the performance degradation observed in the trend data of FIG. 3, where timing margins deteriorate substantially under certain skew conditions between WCK and RCK.

To compensate for this degraded self-timing, additional gate delays are introduced on the dummy read bitlines. While functional, this results in power, performance, and area (PPA) loss at process, voltage, and temperature as well as signoff (PVT) corners because at these corners the additional delay is not necessary. Thus, the need to add these compensatory delays directly impacts the overall performance of the SRAM system, creating an undesirable trade-off between reliability and efficiency.

This coupling problem represents a fundamental challenge in modern high-density SRAM designs where simultaneous read and write operations are increasingly common. As such, further development is needed.

### SUMMARY

This disclosure relates to a self-timed static random access memory (SRAM) device. The SRAM device includes an SRAM bank with multiple SRAM cells arranged in rows and columns, where each SRAM cell connects to a read wordline, a write wordline, and at least one bitline. The device has a dummy circuit with a dummy read row and a dummy read column, a dummy read bitline connected to the dummy read column, and a dummy read wordline and complementary dummy read wordline extending through the dummy read row and dummy read column. These dummy wordlines have a physical arrangement that mimics the proximity relationship between the read wordline and write wordline in the SRAM bank. A dummy read decoder activates the dummy read wordline in response to a read operation and activates the complementary dummy read wordline when the read operation is expected to cause coupling effects between the read wordline and write wordline. This activation of the complementary dummy read wordline creates coupling effects between the dummy wordlines that correspond to coupling effects between the actual read and write wordlines. Control circuitry activates sense amplifiers for reading data from the SRAM bank based on a state change of the dummy read bitline.

The read operation may cause coupling effects between the read wordline and write wordline during simultaneous read and write operations to the SRAM bank. The dummy read decoder may not activate the complementary dummy read wordline when the read operation is not expected to cause coupling effects. The physical proximity relationship may include specific spacing and metal layer arrangement matching that between the read and write wordlines in the SRAM bank. The dummy read decoder may determine whether the read operation is expected to cause coupling effects based on concurrent activation of a write operation. The dummy read decoder may generate the complementary dummy read wordline signal with a timing relationship to the dummy read wordline signal that replicates timing between signals on the write and read wordlines during concurrent operations. The dummy read wordline may follow a snaking path through the dummy read row and column to match delay at a worst-case location on the read wordline in the SRAM bank.

In another aspect, the present disclosure describes a dummy circuit for self-timing an SRAM device. The circuit includes a dummy read row and column, a dummy read bitline connected to the dummy read column, and dummy read and complementary dummy read wordlines extending through the dummy structures. These wordlines are physically arranged to mimic the proximity relationship between read and write wordlines in the SRAM device. A dummy read decoder activates the dummy read wordline during read operations and activates the complementary dummy read wordline when the operation is expected to cause coupling effects. This activation creates corresponding coupling effects between the dummy wordlines that match those between actual read and write wordlines.

The present disclosure also describes a method of self-timing a read operation in an SRAM device. The method involves receiving a read operation request for an SRAM bank having multiple cells arranged in rows and columns, with each cell connected to read and write wordlines and at least one bitline. The method determines if the read operation will cause coupling effects between read and write wordlines, activates a dummy read wordline through dummy structures, and selectively activates a complementary dummy read wordline when coupling effects are expected. The dummy wordlines are physically arranged to mimic the proximity relationship between actual read and write wordlines. This generates corresponding coupling effects between the dummy wordlines. The method detects state changes on a dummy read bitline and activates sense amplifiers based on these changes.

The determination of expected coupling effects may involve detecting concurrent activation of a write operation. The method may include not activating the complementary dummy read wordline when the read operation is not expected to cause coupling effects.

### BRIEF DESCRIPTION OF THE DRAWINGS

FIG. 1 is a block diagram of a prior art self-timed SRAM system.

FIG. 2 shows a cross-sectional view of SRAM wordlines depicting the physical proximity of read and write wordlines, together with an example of the 8T SRAM cells used in the SRAM array of FIG. 1.

FIG. 3 is a graph showing read self-time margin degradation at different skew values between read and write clocks.

FIG. 4 includes graphs of waveforms showing how coupling between write and read wordlines causes distortion of the read wordline signal and reduces bitline discharge current.

FIG. 5 is a block diagram of a dual-port SRAM device with dual banks, dummy rows, and separate read and write dummy decoders, incorporating a modified dummy read decoder.

FIG. 6 is a block diagram of the modified dummy read decoder used in the dual-port SRAM device of FIG. 5.

FIG. 7 shows circuit implementations of both standard and dummy SRAM cells used in the dual-port SRAM device of FIG. 5 along with their interconnections in the array structure.

FIG. 8 includes graphs of waveforms of dummy read wordline and complementary dummy read wordline demonstrating the coupling effects caused therebetween.

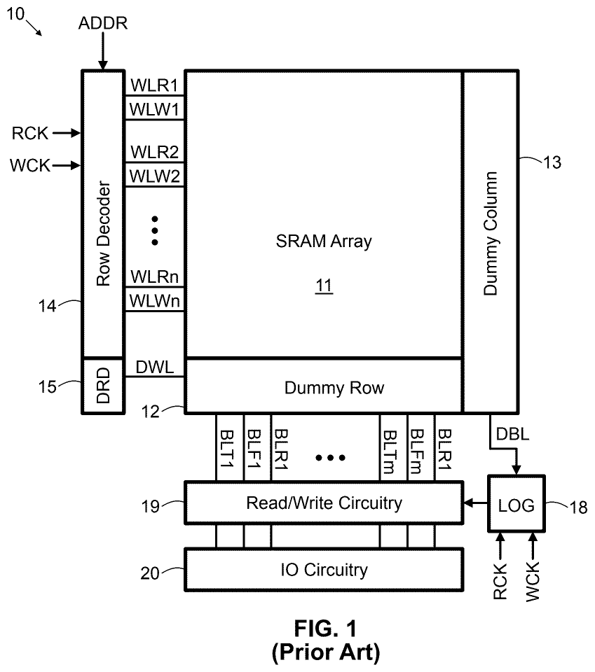

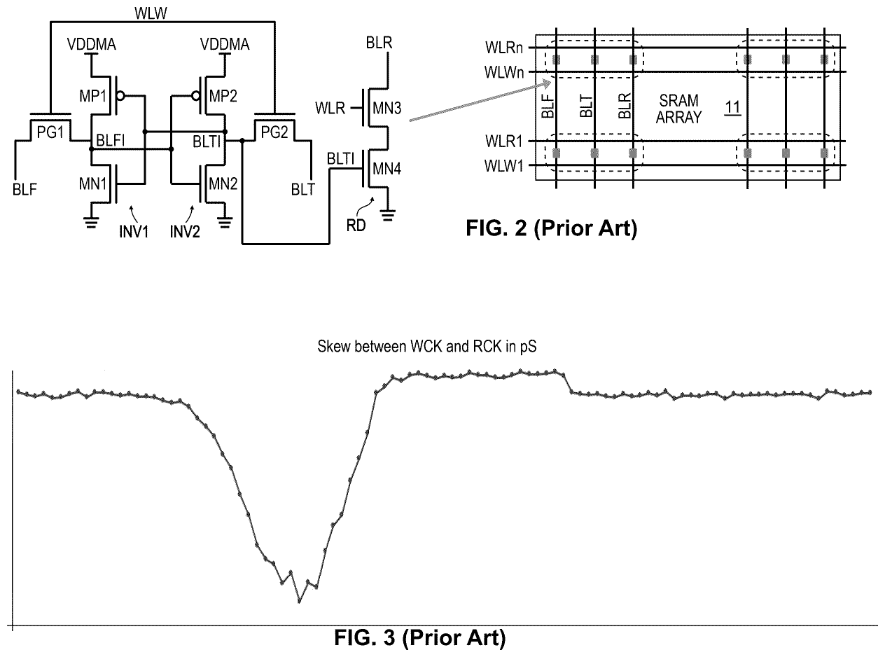

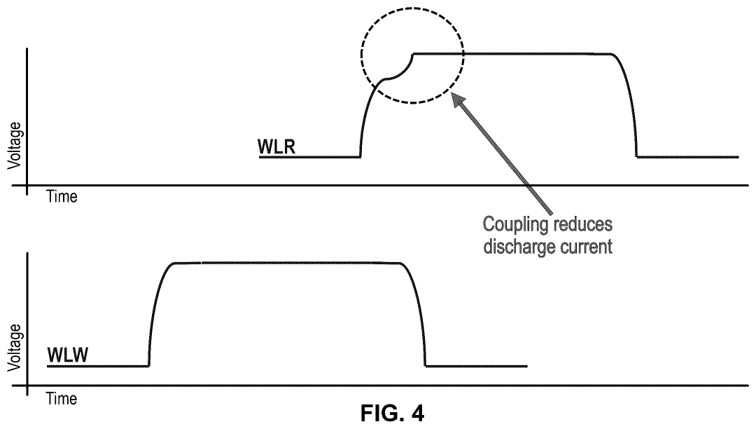

### DETAILED DESCRIPTION

The following disclosure enables a person skilled in the art to make and use the subject matter described herein. The general principles outlined in this disclosure can be applied to embodiments and applications other than those detailed above without departing from the spirit and scope of this disclosure. It is not intended to limit this disclosure to the embodiments shown, but to accord it the widest scope consistent with the principles and features disclosed or suggested herein.

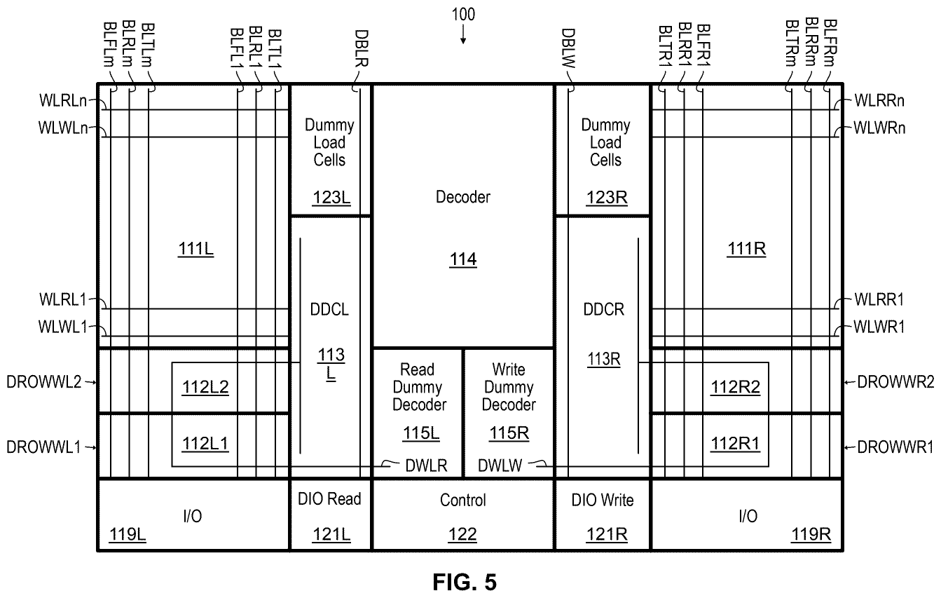

Described initially with reference to FIG. 5 is an SRAM device 100 disclosed herein. The SRAM device 100 includes left SRAM bank 111L and right SRAM bank 111R of 8T SRAM cells.

The SRAM bank 111L is comprised of a grid of multiple rows and columns of the above described 8T SRAM cells, each capable of storing a single bit of data. The intersections of wordlines (WLRL1/WLWL1, . . . , WLRLn/WLWLn) and bitlines (BLFL1/BLTL1, . . . , BLFLm/BLTLm) form the individual SRAM cells of the SRAM bank 111L, with each SRAM cell also including a read bitline (BLRL1, . . . , BLRLn).

The SRAM bank 111R is comprised of a grid of multiple rows and columns of the above described 8T SRAM cells, each capable of storing a single bit of data. The intersections of wordlines (WLRR1/WLWR1, . . . , WLRRn/WLWRn) and bitlines (BLFR1/BLTR1, . . . , BLFRm/BLTRm) form the individual SRAM cells of the SRAM bank 111R, with each SRAM cell also including a read bitline (BLRR1, . . . , BLRRn).

A decoder 114 decodes input addresses and suitably controls the word lines WLRR1/WLWR1, . . . , WLRRn/WLWRn and WLRL1/WLWL1, . . . , WLRLn/WLWLn for performing reads and writes.

Data input/output (I/O) circuitry 119L interfaces SRAM bank 111L with the rest of the system. It delivers the data to be written to the SRAM bank 111L and routes the read data to the appropriate system output. Likewise, data input/output (I/O) circuitry 119R interfaces SRAM bank 111R with the rest of the system. It delivers the data to be written to the SRAM bank 111R and routes the read data to the appropriate system output.

Associated with the SRAM bank 111L is a read dummy column 113L and a read dummy row 112L1, 112L2 (e.g., a single read dummy row spread across two rows due to the illustrated u-turn shown in the middle). A dummy read word line DWLR runs from the read dummy decoder 115L, through the read dummy row 112L1 from right to left, and then up to the read dummy row 112L2 and through the read dummy row 112L2 from left to right, into the read dummy column 113L. The read dummy column 113L includes a dummy read bit line DBLR.

Associated with the SRAM bank 111R is a write dummy column 113R and a write dummy row 112R1, 112R2 (e.g., a single read dummy row spread across two rows due to the illustrated u-turn shown in the middle). A dummy write word line DWLW runs from the write dummy decoder 115R, through the write dummy row 112R1 from left to right, and then up to the write dummy row 112R2 and through the write dummy row 112R2 from right to left, into the write dummy column 113R. The write dummy column 113R includes a dummy write bit line DBLW.

Self-timing of read operations are performed through the use of the read dummy column 113L and read dummy row 112L1, 112L2 to track the worst-case delay for each SRAM cell in the selected row of the selected SRAM bank to be read to reflect its state change onto its corresponding bit lines during a read operation, as well as the worst-case bit line delay during a read operation.

For read operations, the decoder 114 decodes the input address and asserts the appropriate read wordline WLR activating the corresponding SRAM cell in SRAM bank being read.

Concurrently, a dummy read operation is performed, which begins with the appropriate dummy read decoder 115L or 115R performing a dummy decode (to imitate the delay of the decoder 114) and selection of the dummy read word line DWLR, resulting in state change of the dummy read bit line DBLR. When the dummy read bit line DBLR has changed state as confirmed by the dummy read I/O 121L or 121R to emulate the delay of a worst performance case SRAM cell changing state to drive its associated bit lines, it can be inferred that the bit lines have sufficiently changed state to be read and that sense amplifiers within the I/O circuitry 119L or 119R can be turned on to read the selected row in the selected SRAM bank 111L or 111R. Therefore, at this point the control circuitry 122 activates (for example, through the assertion of a sense amplifier enable signal (SAEN)) the appropriate sense amplifiers within the appropriate set of I/O circuitry 119L or 119R.

In this process, dummy load cells 123L and 123R serve to match the capacitance on the dummy bit line DBLR to the capacitance on the actual bit lines. Also note the snaking path of the dummy read bit line DBLR through both the dummy read column 113L and the dummy read rows DROWWL1, DROWWL2 (112L1, 112L2), helping match the delay on the dummy read word line DWLR to the delay at the worst location on the actual read word line WLR.

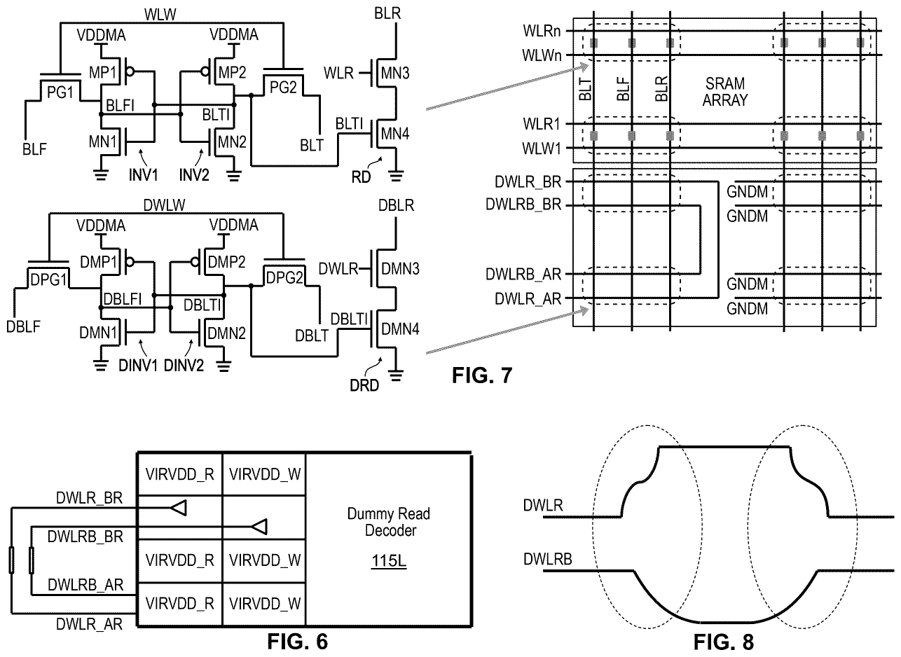

While FIG. 5 shows DWLR as a single line for simplicity, this represents the physical dummy read wordline that is driven with different signal states at different times during the read operation cycle, as further detailed in FIGS. 6 and 8.

FIG. 6 illustrates a detailed view of the read dummy decoder 115L shown in FIG. 5. The read dummy decoder 115L includes multiple voltage domains, with VIRVDD_R and VIRVDD_W voltage supplies arranged in columns. VIRVDD_R (Virtual VDD Read) is the power supply that supplies the read wordline driver circuits within the decoder, while VIRVDD_W (Virtual VDD Write) is the power supply that typically drives the write wordline buffer circuits. In this implementation, a set of the transistors that would contribute to generating VIRVDD_W has been replaced with drivers that generate the DWLRB (complementary read wordline) signal.

The decoder is shown connected to four signal lines representing pieces of the dummy read wordline DWLR and the DWLR_B. DWLR_BR and DWLR_AR together physically form DWLR, and DWLRB_BR and DWLRB_AR together physically form DWLRB. The arrangement in the read dummy decoder creates a drive structure for both DWLR and DWLRB signals that purposely causes a coupling effect between DWLR and DWLRB that mimics the coupling effect between, for example, WLW and WLR. Indeed, the physical proximity of DWLR and DWLRB in the dummy decoder mimics the actual proximity relationships of the read and write wordlines in the array. Thus, in situations where coupling between WLW and WLR would be a concern, such as a simultaneous write and a simultaneous read, DWLRB can be generated as a complementary signal to DWLR without a skew between them, causing the same degradation on the DWLR signal as will occur on the WLR signal. This therefore provides for proper self-timing.

The read dummy decoder 115L may be configured to determine whether a read operation is expected to cause a coupling effect based on concurrent activation of a write operation to the SRAM bank. For instance, when a read operation and a write operation are activated simultaneously, the decoder 114 will activate both a read wordline and a write wordline, creating a coupling effect between them. In this scenario, the read dummy decoder 115L detects this concurrent operation and activates both DWLR and DWLRB to replicate the same coupling effect in the dummy circuit.

FIG. 7 shows the layout and sample bitcells for this design of a dual-port SRAM in which there are both dummy read word lines (DWL) and complementary dummy read word lines (DWLB). In a dual-port SRAM cell such as those in the banks 111L and 111R in FIG. 5, the storage elements (8T transistors) are formed by a pair of cross-coupled inverters INV1 (series connected CMOS transistors MP1, MN1) and INV2 (series connected CMOS transistors MP2, MN2). These inverters INV1, INV2 maintain a stable state representing the stored bit value at nodes BLTI (Bitline True Internal) and BLFI (Bitline False Internal). Pass gates PG1 and PG2 connect these internal storage nodes to external bitlines BLF (Bitline False) and BLT (Bitline True) and are controlled by the write wordline (WLW).

For read operations, a separate read path is formed by transistors MN3 and MN4 series connected between BLR and ground, which are controlled by the read wordline (WLR) and the value at BLTI. When WLR is activated, depending on the data stored in the cell, the read bitline (BLR) is either discharged through MN3 and MN4 to ground or remains at its precharged state.

Also shown is a dummy SRAM cell such as those in dummy banks 112L1, 112L2, 112R1, 112R2 of FIG. 5 mirrors the structure of the 8T cells used in the banks 111L and 111R. It includes a pair of dummy cross-coupled inverters DINV1 (series connected CMOS transistors DMP1, DMN1) and DINV2 (series connected CMOS transistors DMP2, DMN2), dummy pass gates DPG1, DPG2 which selectively connect internal storage nodes DBLFI and DBLTI to external dummy bitlines DBLF and DBLT and are connected by dummy word line DWLW for write oprations. Dummy read transistors DMN3, DMN4 form the dummy read path, are controlled by the value at DBLTI and DWLR, and connect to DBLR.

The illustrated array structure shows how the standard cells and dummy cells are arranged in relation to each other. The top portion of the layout represents the main SRAM array with standard cells at intersections of wordlines and bitlines. Below the main array, four dummy wordlines pieces are shown, namely DWLR_BR, DWLRB_BR, DWLRB_AR, and DWLR_AR. As explained earlier, DWLR_BR and DWLRB_AR form dummy wordline DWLR, and DWLRB_BR and DWLRB_AR form complementary dummy wordline DWLRB.

FIG. 8 illustrates the timing relationship between the dummy read wordline (DWLR) and its complementary signal (DWLRB), showing the actual waveforms that would appear on the DWLR line from FIG. 5 and its complementary signal as driven by the dummy read decoder 115L of FIG. 6. The waveforms show the DWLR signal transitioning from low to high and back to low, while the DWLRB signal simultaneously transitions from high to low and back to high. These complementary signals correspond to the DWLR_BR/DWLR_AR and DWLRB_BR/DWLRB_AR outputs from the read dummy decoder 115L shown in FIG. 6. The physical proximity between DWLR and DWRLB purposely causes a coupling effect between DWLR and DWLRB that mimics the coupling effect between, for example, WLW and WLR.

As illustrated in FIG. 8, the dummy read decoder generates the complementary dummy read wordline signal (DWLRB) with a timing relationship to the dummy read wordline signal (DWLR) that replicates the timing relationship between signals on the write wordline (WLW) and the read wordline (WLR) during concurrent read and write operations. This timing replication provides for accurate self-timing. When WLR and WLW are activated simultaneously in the actual array, there is a specific time-dependent interaction between their signals, including rise time degradation and potential glitches due to coupling. The dummy read decoder ensures that DWLR and DWLRB exhibit this same time-dependent behavior, allowing the self-timing mechanism to accurately account for these effects when determining the appropriate time to enable sense amplifiers.

As explained, the resulting self-timing function is now correct due to the mimicking of the coupling effect between WLW and WLR. The read dummy decoder 115L is configured to determine whether a read operation is expected to cause a coupling effect based on concurrent activation of a write operation to the SRAM bank. For instance, when a read operation and a write operation are activated simultaneously, the decoder 114 will activate both a read wordline and a write wordline, creating a coupling effect between them.

As illustrated in FIG. 8, the dummy read decoder generates the complementary dummy read wordline signal (DWLRB) with a timing relationship to the dummy read wordline signal (DWLR) that replicates the timing relationship between signals on the write wordline (WLW) and the read wordline (WLR) during concurrent read and write operations. This is so that the self-timing mechanism accurately accounts for coupling effects when determining when to enable sense amplifiers.

Additionally, in situations and operating corners where a coupling effect between WLW and WLR is not necessary (e.g., when a read and a write are not being performed simultaneously), DWLRB can simply not be generated by the read dummy decoder 115L when DWLR is generated. This way, a coupling effect between DWLR and DWLRB is generated when there is expected to be a coupling effect between WLW and WLR, but is not generated when there is not expected to be a coupling effect between WLW and WLR.

The SRAM device described herein offers multiple advantages over conventional designs. By implementing the dummy read and write structures with matched delays and coupling effects, the self-timing mechanism provides for proper performance across varying operating conditions and process corners. The ability to selectively generate the complementary dummy read wordline (DWLRB) signal provides flexibility to adapt to different coupling scenarios, enabling more efficient operation in various modes. This architecture therefore delivers improved read/write reliability, reduced power consumption, and enhanced operational stability across different process and operating corners.

Finally, it is evident that modifications and variations can be made to what has been described and illustrated herein without departing from the scope of this disclosure. Although this disclosure has been described with a limited number of embodiments, those skilled in the art, having the benefit of this disclosure, can envision other embodiments that do not deviate from the disclosed scope. Furthermore, skilled persons can envision embodiments that represent various combinations of the embodiments disclosed herein made in various ways.

Indeed, while the embodiments described above detail a specific implementation with 8T SRAM cells, it should be understood that the principles of this self-timing mechanism can be broadly applied to any dual-port memory design regardless of the specific cell architecture. The core concept of replicating coupling effects between wordlines in a dummy circuit to achieve accurate self-timing is applicable to various dual-port memory designs utilizing other cell topologies than those shown herein. The dummy read wordline architecture and selective activation of complementary dummy read wordlines can be adapted to different memory structures, operating voltages, and process technologies. For example, in alternative embodiments, the dummy circuit structure could be modified to accommodate different array layouts, while maintaining the proximity relationship between the dummy read wordlines and complementary dummy read wordlines that mimics the physical relationship between the actual read and write wordlines in the array. This flexibility makes the described approach valuable across a wide range of applications requiring precise self-timing in dual-port memory designs, from low-power mobile devices to high-performance computing systems.

1. A self-timed static random access memory (SRAM) device, comprising:
an SRAM bank comprising a plurality of SRAM cells arranged in rows and columns, wherein each SRAM cell is coupled to a read wordline, a write wordline, and at least one bitline;
a dummy circuit comprising:
a dummy read row and a dummy read column;
a dummy read bitline coupled to the dummy read column;
a dummy read wordline and a complementary dummy read wordline extending through the dummy read row and the dummy read column, the dummy read wordline and the complementary dummy read wordline being physically arranged within the dummy circuit with a proximity relationship that mimics a physical proximity relationship between the read wordline and the write wordline in the SRAM bank; and
a dummy read decoder configured to activate the dummy read wordline in response to a read operation and to activate the complementary dummy read wordline in response to the read operation being one expected to cause a coupling effect between the read wordline and the write wordline;
wherein the activation of the complementary dummy read wordline causes coupling effects between the dummy read wordline and the complementary dummy read wordline that correspond to coupling effects between the read wordline and the write wordline;
control circuitry configured to activate sense amplifiers for reading data from the SRAM bank based on a state change of the dummy read bitline.

2. The SRAM device of claim 1, wherein the read operation expected to cause a coupling effect between the read wordline and the write wordline comprises a simultaneous read and write operation to the SRAM bank.

3. The SRAM device of claim 1, wherein the dummy read decoder is configured to not activate the complementary dummy read wordline in response to the read operation being one not expected to cause a coupling effect between the read wordline and the write wordline.

4. The SRAM device of claim 1, wherein the physical proximity relationship of the dummy read wordline and the complementary dummy read wordline includes a specific spacing and metal layer arrangement matching that between the read wordline and write wordline in the SRAM bank.

5. The SRAM device of claim 1, wherein the dummy read decoder is configured to determine whether the read operation is expected to cause a coupling effect based on concurrent activation of a write operation to the SRAM bank.

6. The SRAM device of claim 1, wherein the dummy read decoder is configured to generate the complementary dummy read wordline signal with a timing relationship to the dummy read wordline signal that replicates a timing relationship between signals on the write wordline and the read wordline during concurrent read and write operations.

7. The SRAM device of claim 1, wherein the dummy read wordline follows a snaking path through the dummy read row and the dummy read column to match a delay at a worst-case location on the read wordline in the SRAM bank.

8. A dummy circuit for self-timing a static random access memory (SRAM) device, the dummy circuit comprising:
a dummy read row and a dummy read column;
a dummy read bitline coupled to the dummy read column;
a dummy read wordline and a complementary dummy read wordline extending through the dummy read row and the dummy read column, the dummy read wordline and the complementary dummy read wordline being physically arranged within the dummy circuit with a proximity relationship that mimics a physical proximity relationship between a read wordline and a write wordline in the SRAM device; and
a dummy read decoder configured to activate the dummy read wordline in response to a read operation of the SRAM device and to activate the complementary dummy read wordline in response to the read operation being one expected to cause a coupling effect between the read wordline and the write wordline;
wherein the activation of the complementary dummy read wordline causes coupling effects between the dummy read wordline and the complementary dummy read wordline that correspond to coupling effects between the read wordline and the write wordline.

9. The dummy circuit of claim 8, wherein the read operation expected to cause a coupling effect between the read wordline and the write wordline comprises a simultaneous read and write operation to the SRAM device.

10. The dummy circuit of claim 8, wherein the dummy read decoder is configured to not activate the complementary dummy read wordline in response to the read operation being one not expected to cause a coupling effect between the read wordline and the write wordline.

11. The dummy circuit of claim 8, wherein the physical proximity relationship of the dummy read wordline and the complementary dummy read wordline includes a specific spacing and metal layer arrangement matching that between the read wordline and write wordline in the SRAM device.

12. The dummy circuit of claim 1, wherein the dummy read decoder is configured to determine whether the read operation is expected to cause a coupling effect based on concurrent activation of a write operation to the SRAM device.

13. A method of self-timing a read operation in a static random access memory (SRAM) device, comprising:
receiving a read operation request for reading data from an SRAM bank, wherein the SRAM bank comprises a plurality of SRAM cells arranged in rows and columns with each SRAM cell coupled to a read wordline, a write wordline, and at least one bitline;
determining whether the read operation is expected to cause a coupling effect between a read wordline and a write wordline in the SRAM bank;
activating a dummy read wordline extending through a dummy read row and a dummy read column in response to the read operation;
selectively activating a complementary dummy read wordline extending through the dummy read row and the dummy read column in response to determining that the read operation is expected to cause the coupling effect between the read wordline and the write wordline, wherein the dummy read wordline and the complementary dummy read wordline are physically arranged with a proximity relationship that mimics a physical proximity relationship between the read wordline and the write wordline;
generating coupling effects between the dummy read wordline and the complementary dummy read wordline that correspond to coupling effects between the read wordline and the write wordline;
detecting a state change on a dummy read bitline coupled to the dummy read column; and
activating sense amplifiers for reading data from the SRAM bank based on the detected state change of the dummy read bitline.

14. The method of claim 1, wherein determining whether the read operation is expected to cause the coupling effect comprises detecting concurrent activation of a write operation to the SRAM bank.

15. The method of claim 1, further comprising:
not activating the complementary dummy read wordline in response to determining that the read operation is not expected to cause a coupling effect between the read wordline and the write wordline.
